(19) United States
(12) Patent Application Publication
(10) Pub. No.: US 2007/0223069 A1
(43) Pub. Date: Sep. 27, 2007

(54) Image pickup apparatus for minimizing variation in black level correction between plural outputs and a method of driving the same

(75) Inventor: Motoari Ota, Asaka-shi (JP)

Correspondence Address: BIRCH STEWART KOLASCH & BIRCH, PO BOX 747, FALLS CHURCH, VA, 22040-0747, US

(73) Assignee: FUJIFILM Corporation

(21) Appl. No.: 11/640,397

(22) Filed: Dec. 18, 2006

(30) Foreign Application Priority Data
Mar. 23, 2006 (JP) 2006-81557

(51) Int. Cl. G03F 3/08

(52) U.S. Cl. 358/529; 358/474

(57) ABSTRACT

An image pickup apparatus includes an image sensor for photoelectrically converting light incident from a field to produce an image signal via al least two output portions. The temperature of the image sensor is sensed. The image sensor is driven such that the image signal is output via one of the output portions if the temperature sensed is higher than a predetermined value inclusive or is output via the two output portions if the former is lower than the latter. A black level corrector uses, when the image signal is output via one of the output portions, a predetermined single value as a reference to execute black level correction on the image signal, or uses, when the image signal is output via the two output portions, a particular predetermined value as a reference to execute black level correction on each of image signals output from respective output portions.

### BACKGROUND OF THE INVENTION

1. Field of the Invention

The present invention relates to an image pickup apparatus and a method of driving the same, and more particularly to an image pickup apparatus of the type executing black level correction and a method of driving the same.

2. Description of the Background Art

To read out signal charges from a solid-state image sensor, such as a charge-coupled device (CCD) type of image sensor, there is available a so-called one-output reading system configured to output signal charges via a single output portion positioned on, e.g., a horizontal transfer path. Another reading system available for the same purpose is a two-output system practicable with a solid-state image sensor, such as CCD, having its image sensing surf ace, or array of photosensitive cells, divided into two or more subregions and is configured to output signal charges read out of each subregion via a particular output portion provided on, e.g., a horizontal transfer path. The latter reading system will hereinafter be referred to as a multiple-line reading system, as distinguished from the one-output reading system.

Typical of the multiple-line reading system mentioned above is a two-output reading system configured to read out signal charges from each of two subregions of an image sensing surface, which are separate from each other in the up-and-down or vertical direction or the right-and-left or horizontal direction, via a respective output portion. Generally, the two-output reading system is considered to be higher in reading speed than the one-output reading system because the former reads out signal charges from two divided subregions of the image sensing surface.

On the other hand, as processing for adjusting the brightness of an image captured, black level correction is conventional. Black level correction is configured to subtract a black level signal from an image signal produced as a result of pickup, the black level signal being previously obtained and stored with the effective region of the image sensing surface to be adapted sensitive with incident light, i.e., a valid pixel region optically shielded.

More specifically, even though the valid pixel region mentioned above is shielded, i.e., even through a mechanical shutter is closed, dark current and other electric charges have already been generated and stored in the valid pixel region due to various causes, and may undesirably be added to an image signal resulting from pickup. In light of this, black level correction may be required in which the signal level of the valid pixel region, when optically shielded, is determined beforehand at the time of automatic exposure/focusing (AE/AF) control or similar preliminary pickup, and the shielded level thus determined is used as a black level to subtract the black level from an image signal for thereby providing an image with original brightness recovered. Conventional black level correction schemes are disclosed in, e.g., Japanese patent laid-open publication No. 221926/1994.

For black level correction, it has been customary to a solid-state image sensor to clamp, at the time of preliminary pickup, a signal level in its optical black (OB) region surrounding the valid pixel region and adapted to be insensitive to an incident light beam. A difference of the shielded level of the valid pixel region from the clamped signal level is usually referred to as an OB step. If the OB step of an image signal, after digitalized, is constant at all times, it is possible to execute accurate black level correction. In practice, however, the OB step of the image sensor varies in dependence upon the temperature of the devices, such as image sensor, and the exposure time of imaging. Also, it can readily be presumed that an image sensor having its image sensing region bisected in the right-and-left direction in order to output signal charges via two output portions may be subject to the variation of the OB step different between the bisected subregions with respect to temperature, exposure time or similar parameter.

Further, with an image sensor of the type provided with two output portions for outputting signal charges, as stated above, it is likely that gain-controlled amplifiers, for example, included in the two outputting portions are different in temperature characteristic from each other with the result that the deviation from the black level obtained during preliminary pickup is different between the right and left subregions of the image sensing region.

For the reasons described above, when two-output read out is executed when the temperature of the image sensor is high or when long-lime exposure is under way, brightness or color is apt to be different between the right and left areas of a single frame of image.

### SUMMARY OF THE INVENTION

It is an object of the present invention to provide an image pickup apparatus insuring high-quality images with a minimum of difference in brightness and color shifts between the right and left regions of an image ascribable to black level correction even when the temperature of an image sensor, usually read in a two-output readout mode, rises above a preselected level.

An image pickup apparatus of the present invention includes an image sensor including a plurality of output portions and configured to photoelectrically convert light incident from a field to thereby produce an image signal via the output portions. The temperature of the image sensor is sensed by a temperature sensor. The image sensor is driven by a driver such that the image signal is output via one of the output portions if the temperature sensed by the temperature sensor is higher than a preselected value inclusive or is output via at least two of the output portions if the former is lower than the latter. A black level corrector use, when the image signal is output via one of the output portions, a preselected single value as a reference to execute black level correction on the image signal or uses, when the image signal is output via at least two of the output portions, a particular preselected value as a reference to execute black level correction on each of image signals output from the respective output portions.

Also, an image pickup apparatus of the present invention includes an image sensor including a plurality of output portions and configured to photoelectrically convert light incident from a field to thereby produce an image signal via the output portions. A signal level monitor monitors the signal level of an optical black (OB) region surrounding the valid pixel region of the image sensor. A driver drives the image sensor such that the image signal is output via one of the output portions if the signal level monitored is higher than a preselected value inclusive or is output via at least two of the output portions if the former is lower than the latter. A black level corrector uses, when the image signal is output via one of the output portions, a preselected single value as a reference to execute black level correction on the image signal or uses, when the image signal is output via at least two of the output portions, a particular preselected value as a reference to execute black level correction on each of image signals output from the respective output portions.

Further, an image pickup apparatus of the present invention includes an image sensor including a plurality of output portions and configured to photoelectrically convert light incident from a field to thereby produce an image signal via the output portions. A timer counts, or measures, a period of time over which the image sensor outputs an image signal for the through image of the field when a power supply is on. A driver drives the image sensor such that the image signal is output via one of the output portions if the period of time counted is longer than a preselected value inclusive or is output via at least two of the output portions if the former is shorter than the latter. A black level corrector uses, when the image signal is output via one of the output portions, a preselected single value as a reference to execute black level correction on the image signal or uses, when the image signal is output via at least two of the output portions, a particular preselected value as a reference to execute black level correction on each of image signals output from the respective output portions.

A particular method of driving each of the image pickup apparatuses stated above is also disclosed.

### BRIEF DESCRIPTION OF THE DRAWINGS

The objects and features of the present invention will become more apparent from consideration of the following detailed description taken in conjunction with the accompanying drawings in which:

FIG. 1 is a schematic block diagram showing a preferred embodiment of the image pickup apparatus in accordance with the present invention;

FIG. 2 is a conceptual view of the image sensing surface useful for understanding a one-output and a two-output readout mode available with a CCD image sensor included in the illustrative embodiment shown in FIG. 1;

FIG. 3 is a conceptual view of a valid pixel region and an OB region constituting the image sensing surface of the CCD image sensor included in the illustrative embodiment and bisected in the right-and-left direction each specifically;

FIG. 4 is a flowchart useful for understanding a specific procedure of driving the image pickup apparatus in accordance with the illustrative embodiment;

FIG. 5 is a schematic block diagram, like FIG. 1, showing an alternative embodiment of the image pickup apparatus in accordance with the present invention;

FIG. 6 is a flowchart, like FIG. 4, useful for understanding a specific procedure of driving the image pickup apparatus shown in FIG. 5;

FIG. 7 is a schematic block diagram, like FIG. 1, showing another alternative embodiment of the image pickup apparatus in accordance with the present invention; and

FIG. 8 is a flowchart, like FIG. 4, useful for understanding a specific procedure of driving the image pickup apparatus shown in FIG. 7.

### DESCRIPTION OF THE PREFERRED EMBODIMENTS

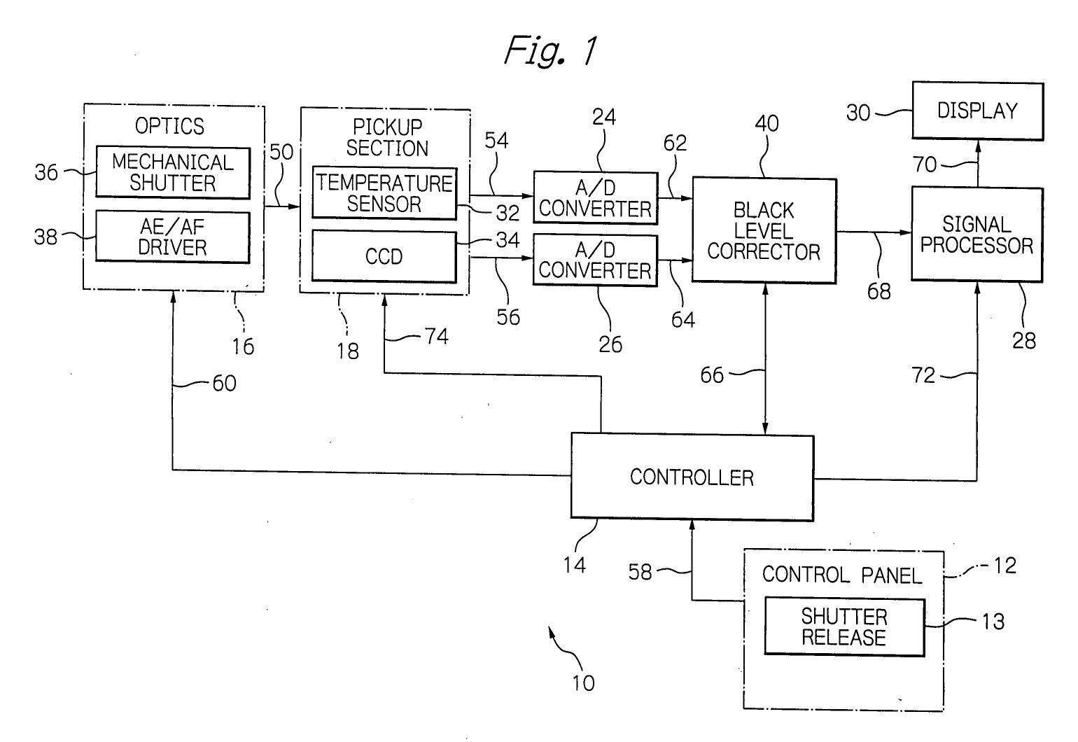

Referring to FIG. 1 of the drawings, a preferred embodiment of the image pickup apparatus in accordance with the present invention is implemented as a digital camera by way of example. As shown, the digital camera, generally 10, includes an image pickup section 18 made up of a solid-state image sensor, such as charge-coupled device (CCD) type of image sensor, 34 and a temperature sensor 32.

The CCD image sensor 34 is configured to produce an image signal by photoelectrically converting light incident thereto from a subject field to be imaged. More specifically, the CCD image sensor 34 is adapted for converting light 50 fed from optics 16, which will be described later specifically, to signal charges and outputting the signal charges in the form of electrical image signal. The CCD image sensor 34 may, of course, be replaced with a CMOS (Complementary Metal Oxide Semiconductor) image sensor, if desired.

The temperature sensor 32 is adapted to monitor the temperature of the CCD image sensor 34. While the temperature sensor 32 may be implemented by a specific temperature sensor taught in Japanese patent laid-open publication No. 221926/1994 mentioned previously, any other suitable type of temperature sensor may be used so long as it is sufficiently small in size.

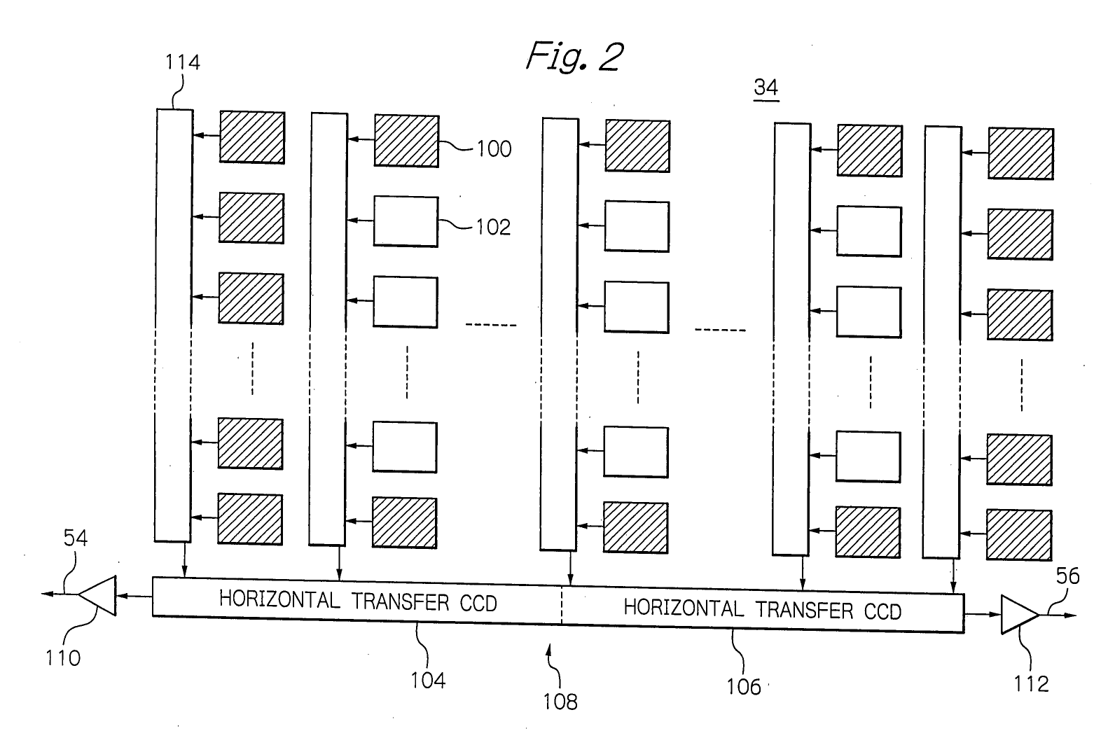

FIG. 2 conceptually shows the configuration of the CCD image sensor 34 in detail. As shown, the CCD image sensor 34 includes an array of photosensitive cells, or photodiodes, 100 and 102, a horizontal transfer path 108 made up of a CCD, output portions 110 and 112 and corresponding vertical transfer paths also made up of CCDs 114. The photodiodes 100 and 102 are respectively arranged in optical black (OB) regions and a valid pixel region, as will be described specifically hereinafter.

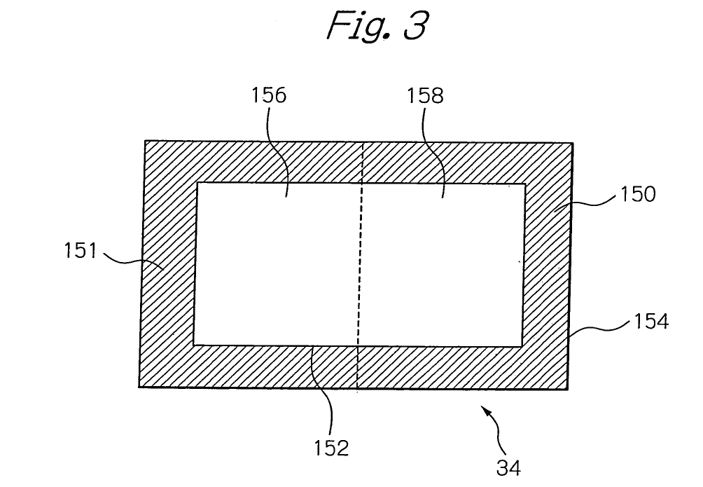

As shown in FIG. 3 specifically, the CCD image sensor 34 has an image sensing surface 154, formed by the array of photosensitive cells, divided into, or formed by, a valid pixel region 152 and OB regions 150 and 151 surrounding the valid pixel region 152. The OB regions 150 and 151 are covered with, e.g., an aluminum film or similar optical shield film for preventing light from being incident to the photodiodes 102, FIG. 2. The valid pixel region 152 is bisected into a right subregion 158 and a left subregion 156 at the center thereof in the right-and-left direction, as viewed in FIG. 3.

Referring again to FIG. 2, the photodiodes 100 and 102 each are arranged such that light is effectively incident on a junction between a P-type and an N-type semiconductor, allowing a photo conduction current to easily flow therethrough. In response to light incident, each photodiode 100 or 102 generates and stores a corresponding signal charge therein and then feeds it to the vertical transfer path 114 to which the photodiode is connected. The vertical transfer paths 114 sequentially deliver the charges thus input from the photodiodes 100 and 102 to the-horizontal transfer path 108.

The horizontal transfer path 108 is constituted by a couple of horizontal transfer paths 104 and 106 and adapted to selectively transfer the signal charges fed from the vertical transfer paths 114 to one or both of the output portions 110 and 112 via one or both of the horizontal transfer paths 104 and 106, respectively. More specifically, the horizontal transfer path 108 outputs the signal charges via either one of the output portions 110 and 112 in the one-output readout mode, or outputs them via both of the output portions 110 and 112 in the two-output readout mode. In the illustrative embodiment, such a selective outputting method is controlled by a drive signal output from a controller 14, see FIG. 1, in accordance with the temperature of the CCD image sensor 34.

In the illustrative embodiment, the two-output readout mode is usually executed to cause signal charges generated from photosensitive cells, or pixels, constituting the left half of a single frame of image to be output via the left output portion 110 by way of part of the vertical transfer paths 114 assigned to the above pixels to the left horizontal transfer path 104, and to cause signal charges generated from pixels constituting the right half of the frame to be output via the right output portion 112 by way of the other part of the vertical transfer paths 114 to the right horizontal transfer path 106.

As stated above, in the illustrative embodiment, the output portions 110 and 112 bisect the imaging frame in the right-and-left direction into the right and left subregions, and output signal charges generated from the respective subregions. Of course, the frame may alternatively be bisected in the up-and-down direction or in any other desired configuration. Further, while the illustrative embodiment is shown as including only two output portions 110 and 112, three or more output portions maybe provided and configured to receive signal charges from respective part of the divided screen each. In addition, while signal charges are transferred and output rightward and leftward in the illustrative embodiment, the directions of transfer and output of signal charges are, of course, open to choice.

Generally, the one-output readout mode that causes, in the illustrative embodiment, signal charges fed to the horizontal transfer path 108 to be output via only one of the output portions 110 and 112 is lower in reading speed than the two-output readout mode stated above. Switch over between the one-output and two-output readout modes is executed by the pickup section 18 in response to a control signal 74, see FIG. 1, output from the controller 14. Signals are designated with reference numerals associated with connections on which they are conveyed. The output portions 110 and 112 sequentially deliver the signal charges fed thereto to the outside of the CCD image sensor 34.

The rule of switch over between the one-output and two-output readout modes unique to the illustrative embodiment will be described hereinafter. In normal operation, the pickup section 18 is set to execute the two-output readout mode operation, as stated previously. While the power supply of the camera 10 is turned on, the temperature sensor 32 included in the pickup section 18 constantly monitors the temperature of the CCD image sensor 34 also included in the pickup section 18. As shown in FIG. 1, the camera 10 has a control panel 12 which includes a shutter release button 13 expected to be depressed to its half-stroke position by a first stroke and then to its full-stroke position by a second stroke by the operator of the camera 10, as will be described more specifically later.

When the shutter release button 13 is depressed to its half-stroke position by the operator, a preliminary pickup signal 58 is fed from the control panel 12 to the controller 14, causing the controller 14 to reference the temperature of CCD image sensor 34 being measured by the temperature sensor 32. If the temperature of the CCD image sensor 34 is higher than a preselected reference level T inclusive, the controller 14 delivers a drive signal 74 indicative of the one-output readout mode to the pickup section 18 for thereby causing the CCD image sensor 34 to perform one-output readout. On the other hand, if the temperature of the CCD image sensor 34 is lower than the reference level T, the controller 14 feeds a drive signal 74 indicative of the two-output readout mode to the pickup section 18 as usual. It is to be noted that the reference temperature level T maybe any desired value selected beforehand.

The camera 10 include a couple of analog-to-digital (A/D) converters 24 and 26 connected at one end to the output terminals 54 and 56, see FIG. 2, of the output portions 110 and 112, respectively, and connected at the other end to a black level corrector 40. The A/D converters 24 and 25 are adapted for converting analog signals 54 and 56 to corresponding digital signals 62 and 64, respectively. Digital signals or digital image data 62 and 64 thus output from the A/D converters 24 and 26, respectively, are input to the black level corrector 40. The black level corrector 40 is configured to execute black level correction on the image data 62 and 64 in response to a control signal 66 input from the controller 14.

For black level correction, the black level corrector 40 first measures the shielded levels of the digital image data 62 and 64, that is, measures the level of the image data with the valid pixel region 152 optically shielded. The black level corrector 40 then stores data representative of the shielded level of the image data 62, i.e., the shielded level of the left subregion 156 of the valid pixel region 152, FIG. 3, and the shield level of the image data 64, i.e., the shielded level of the right subregion 158 of the same, as a left and a right shielded level, respectively. The term “shielded level” refers to the signal level of the valid pixel region 152 in a condition where a mechanical shutter 36 to be described later specifically is closed. After storing data representing the right and left shield levels, the black level corrector 40 sends an end-of-storage signal 66 to the controller 14.

In the illustrative embodiment, the pickup section 18 is selectively operable in the one-output or the two-output readout mode in accordance with the temperature of the CCD image sensor 34, as stated earlier. Therefore, in the usual, two-output readout mode, the digital image data 62 and 64 both are input to the black level corrector 40. However, in the one-output readout mode, only the digital image data 62 are input to the black level corrector 40. More specifically, the entire image signal produced from the valid pixel region 152, FIG. 3, is output via the output portion 54, FIG. 2, and then fed to the black level corrector 40 as digital image data 62 via the A/D converter 24. In this case, the black level corrector 40 subtracts the left shielded level from the signal levels of the entire digital image data 62. The black level corrector 40delivers the image data left after the subtraction to a signal processor 28 over a signal line 68.

While in the illustrative embodiment the entire image signal is output via the output portion 54 in the one-output readout mode, as stated above, it may, of course, be output via the other output portion 56, in which case the black level corrector 40 applies black level correction to the digital image data 64.

On the other hand, in the usual, two-output readout mode, the digital image data 64 and 62 produced from the right and left subregions 158 and 156, respectively, both are input to the black level corrector 40. In this case, the black level corrector 40 subtracts the right shielded level from the signal levels of the image data 64 and subtracts the left shielded level from the signal levels of the image data 62, combines the image data left after the subtraction to constitute a single frame of image and then delivers the resulting combined image data to the signal processor 28 over the signal line 68.

The other arrangements of the digital camera 10 will be described hereinafter. The control panel 12 is a manually operable unit configured to send various control signals 58 to the controller 14 for causing the latter to control the camera 10. The shutter release button 13 provided on the control panel 12, as stated previously, sends a particular operation signal 58 to the controller 14 when depressed to each of its half-stroke and full-stroke positions mentioned earlier. The controller 14 is adapted for driving and controlling various circuits connected thereto.

The optics 16 includes a lens system, an iris diaphragm, both not shown, and an automatic exposure/focusing (AE/AF) driver 38 in addition to the mechanical shutter 36 mentioned previously. The mechanical shutter 36 is configured to be opened to start exposure and then closed to end it for thereby defining an exposure time. The AE/AF driver 38 is adapted for controlling the lens system and iris diaphragm in order to control focus and exposure including a shutter speed.

The signal processor 28 is configured to execute gamma correction, synchronization, image conversion, compression coding, display processing and so forth on the digital image data 68 fed from the black level corrector 40 after black level correction. The signal processor 28 delivers the image data thus subjected to such various kinds of processing to a display 30 over a signal line 70. The display 30 is a visual display device including a picture monitor and a display controller associated therewith and is configured to visualize and display an image represented by the image data 70 on its display screen, not shown.

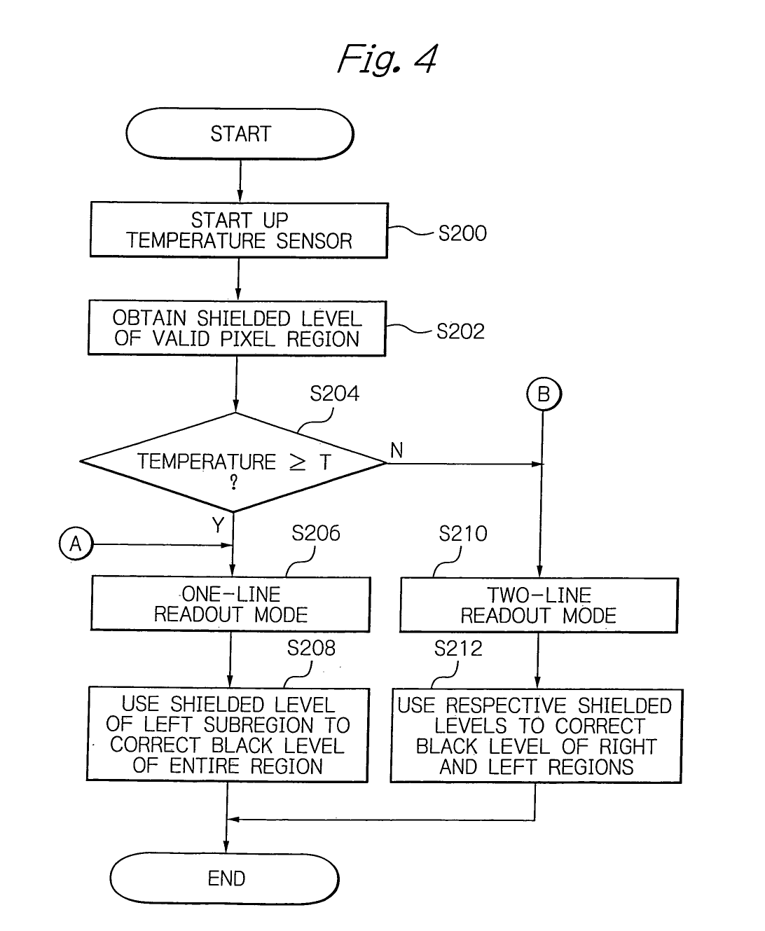

FIG. 4 is a flowchart demonstrating a specific method of driving the digital camera 10 in accordance with the illustrative embodiment. As shown, power is fed from a power supply, not shown, to the pickup section 18, causing the temperature sensor 32 to start monitoring the temperature of the CCD image sensor 34 (step S200).

In the above condition, when the operator of the camera 10 depresses the shutter release button 13 to its half-stroke position by the first stroke, the control panel 12 sends a preliminary pickup signal 58 to the controller 14. In response, the controller 14 closes the mechanical shutter 36 for a moment in order to allow the pickup section 18 to perform the usual, two-output readout mode operation. Consequently, the black level corrector 40 stores signals produced from the right and left subregions 158 and 156 as a right and a left shielded level, respectively. Such a procedure is generally represented by a step S202.

Subsequently, the controller 12 references the temperature of the CCD image sensor 34 being monitored by the temperature sensor 32 and determines whether or not it is higher than the preselected reference level T inclusive (step S204). The step S204 is followed by a step S206 if the answer of the step S204 is positive (Y) or followed by a step S210 if it is negative (N). The steps 202 and 204 described above are sequentially executed while the shutter release button 13 is in its half-stroke position.

When the shutter release button 13 is depressed from its half-stroke position deeper to its full-stroke position by the second stroke, the step S206 or 210 is executed in accordance with the temperature of the CCD image sensor 34. In the step S206, the CCD image sensor 34 is driven in the one-output readout mode because, when the above temperature is higher than the reference level T, the one-output readout mode obviates differences in brightness and color shifts between the right and left subregions 158 and 156, and thus implements higher image quality than the usual, two-output readout mode. Digital image data 62 produced in the one-output readout mode are input to the black level corrector 40.

After the step S206, the black level corrector 40 subtracts the left shielded level from the digital image data 62, i.e., the signal levels of the entire valid pixel region 152 and then delivers digital image data left as a result of subtraction to the signal processor 28 via the signal line 68. The left shielded level used in the step S208 may, of course, be replaced with the right shielded level.

On the other hand, in the step S210 executed when the actual temperature is lower than the reference temperature T, the CCD image sensor 34 is driven in the usual, two-output readout mode to execute actual pickup. This stems from the assumption that at temperature lower than the reference temperature T the OB step is not different between the right and left subregions 158 and 156. In such a condition, even if the right and left subregions 158 and 156 are subject to black level correction independently of each other, differences in brightness, color shifts and other image defects do not occur, and in addition the reading time is reduced.

In a step S212 following the step S210, the black level corrector 40 subtracts the right shielded level and left shielded level from the signal levels of the image data 64 and 62, respectively, derived from the right and left subregions 158 and 156. The black level corrector 40 then combines the right and left digital image data left after the subtraction and feeds the resulting combined image data to the signal processor 28 via the signal line 68.

When the temperature of the CCD image sensor 34 is extremely low, the image sensor 34 is also susceptible to the temperature of, e.g., the operator handling the camera 10, so that the two-output readout mode might bring about differences in brightness, colors and so forth between the right and left subregions 158 and 156 due to the influence of the temperature characteristic. In light of this, a threshold value for low temperature may be set beforehand in addition to the threshold for high temperature described above, in which case the one-output readout mode is executed when the actual temperature is lower than the above threshold value.

While in the illustrative embodiment the two-output readout mode is applied to the right and left subregions 158 and 156 of a single frame when the temperature of the CCD image sensor 34 is lower than the reference level T, it maybe similarly applied to an upper and a lower subregion when a single frame is bisected in the up-and-down direction. If desired, the two-output readout mode may even be replaced with a four-output readout mode in which a valid pixel region is quadrisected and read out on a subregion basis.

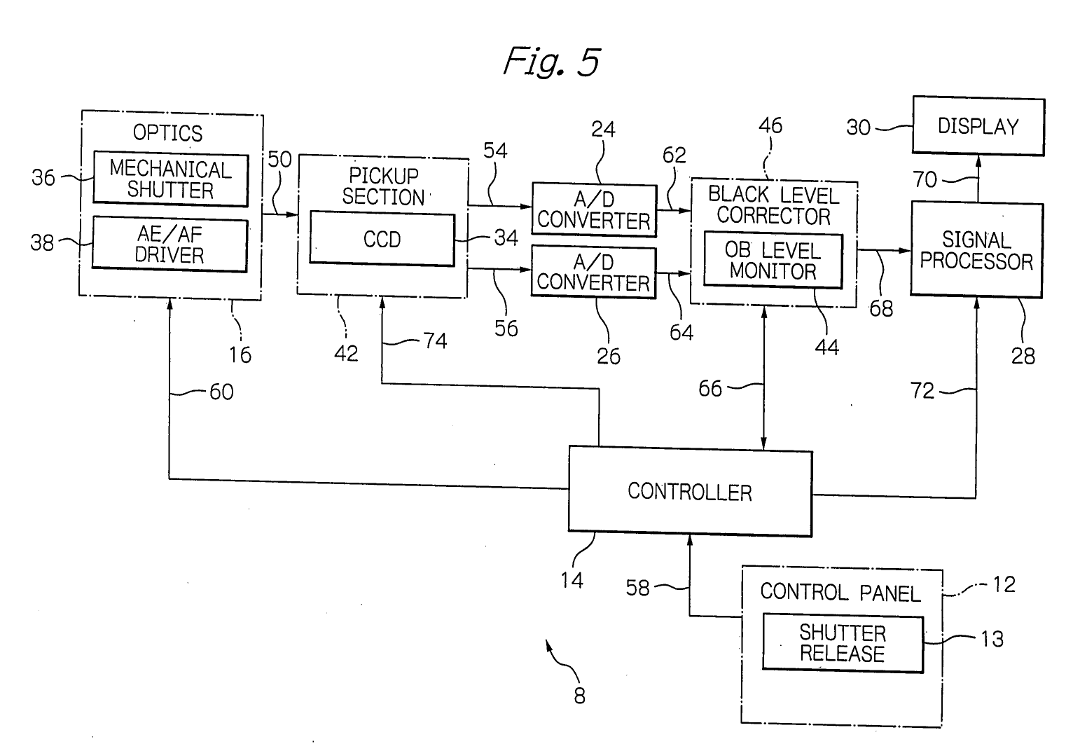

An alternative embodiment of the image pickup apparatus in accordance with the present invention will be described hereinafter with reference to FIG. 5. In FIG. 5, structural parts and elements like those shown in FIG. 1 are designated by identical reference numerals, and detailed description thereof will not be repeated in order to avoid redundancy.

As shown in FIG. 5, a digital camera, generally 8, may be the same as the digital camera 10 of FIG. 1 except that the pickup section 42 does not include a temperature sensor and that the black level corrector 46 includes an OB level monitor 44. The OB level monitor 44 is configured to measure, in response to a control signal 66 fed from the controller 14, the signal levels or OB levels of the OB regions included in the digital image data 62 and 64 input from the A/D converters 24 and 26, respectively. The term “OB levels” refer to the signal levels of the OB regions 150 and 152 shown in FIG. 3.

If the OB levels of the digital image data 62 and 64 thus measured are higher than a preselected threshold value L inclusive, the OB monitor 44 produces a one-output readout signal 66 and feeds it to the controller 14. In response, the controller 14 causes the pickup section 42 to perform one-output readout at the time of actual pickup. On the other hand, if the above OB levels are lower than the preselected threshold value L, the OB monitor 44 produces a two-output readout signal 66 and feeds it to the controller 14. In the latter case, the controller 14 causes the pickup section 43 to perform usual, two-output readout at the time of actual pickup. The preselected threshold value L may be any desired value.

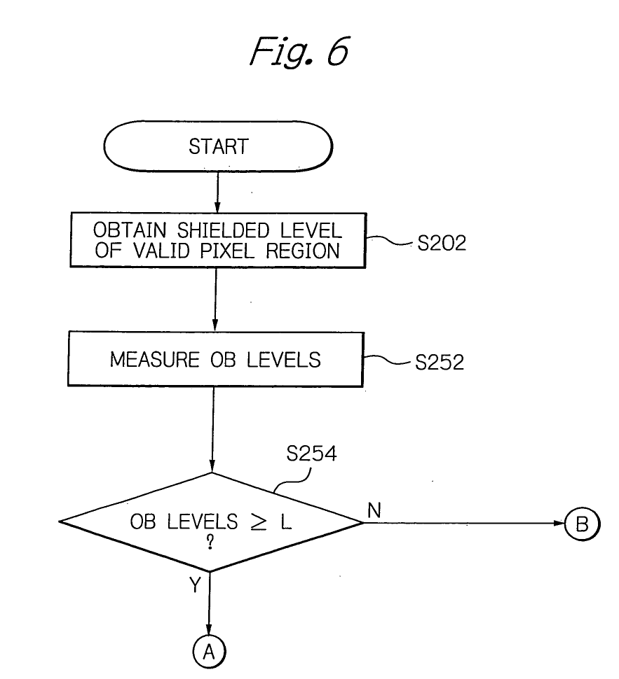

FIG. 6 is a flowchart demonstrating a specific method of driving the digital camera 8 in accordance with the illustrative embodiment. In FIG. 6, the step S202, executed when the shutter release button 13 is depressed to its half-stroke position, is identical with the corresponding step S202 shown in FIG. 4 and will not be described again in order to avoid redundancy. As shown in FIG. 6, in response to an OB level measure signal 66 fed from the controller 14 after the step S202, the black level corrector 46 causes the OB level monitor 44 to measure the OB levels of the digital image data 62 and 64 (step S252)

More specifically, the OB level monitor 44 determines whether or not the OB level of either one of the two OB levels measured is higher than the preselected threshold value L (step S254). If the answer of the step S254 is positive, Y, then the OB level monitor 44 produces a one-output readout signal 66 and feeds it to the controller 14. In response, the controller 14 will execute the step S206, FIG. 4, through a connection A. By contrast, if the answer of the step S254 is negative, N, then the OB level monitor 44 produces a usual, two-output readout signal and feeds it to the controller 14. In the latter case, the controller 14 will execute the step S210, FIG. 4, via a connection B. Such a sequence of steps is executed while the shutter release button 13 is in its half-stroke position.

The control will then proceed to the step S208 or S210, if appropriate, shown in FIG. 4, after the shutter release button 13 is depressed to its full-stroke position as described with the previous embodiment, and therefore will not be described again just for the simplicity.

As stated above, the alternative embodiment switches the method of reading out signal charges generated in the CCD image sensor 34 on the basis of whether or not the OB levels of the OB regions 150 and 151 are higher than the preselected level L inclusive. More specifically, an OB level generally rises with temperature elevation. Therefore, when the above OB levels are higher than the threshold value L, the alternative embodiment determines that the temperature of the CCD image sensor 34 is high, shifts its readout control to the one-output readout mode to perform actual pickup, and then uses the shielded level of the left subregion 156 to execute black level correction with the entire valid pixel region 152. This is because considering that the temperature of the CCD image sensor 34 is presumably high, it is desirable to use the one-output readout mode rather than the usual, two-output readout mode to obviate differences in brightness and color shifts between the right and left regions and enhance image quality.

By contrast, if the OB levels are lower than the threshold value L, then the alternative embodiment determines that the temperature of the CCD image sensor 34 is low, applies the usual, two-output readout mode to actual pickup, and then uses the shielded levels of the two subregions 158 and 156 to execute black level correction with the right and left subregions 158 and 156. This is because considering that the temperature of the CCD image sensor 34 is presumably low, differences in brightness, color shifts and other image defects do not occur even if the right and left subregions 158 and 156 are subject to black level correction independently of each other. In addition, such black level correction is successful to reduce the reading time.

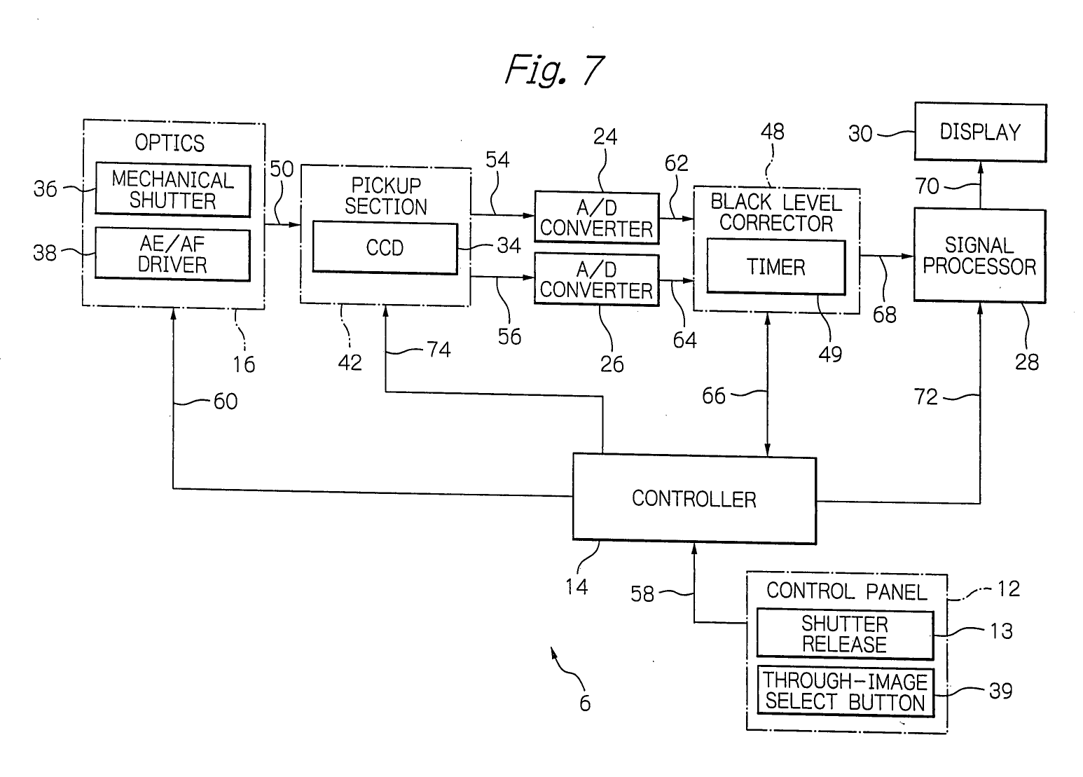

FIG. 7 is a schematic block diagram showing another alternative embodiment of the image pickup apparatus in accordance with the present invention. As shown, a digital camera, generally 6, is similar to the digital camera 10 or 8 shown in FIG. 1 or 5, respectively, except that the pickup section 42 does not include a temperature sensor, that the black level corrector 46 includes a timer 49 in place of the OB level monitor 44, and that the control panel 12 includes a through picture select button 39. In FIG. 7, structural parts and elements like those shown in FIG. 1 or 5 are designated by identical reference numerals, and a detailed description will not be repetitive in order to avoid redundancy.

In the alternative embodiment, when the shutter release button 13 is depressed to its half-stroke position, the black level corrector 48 obtains a right and a left shielded level in the same manner as in the circuitry of FIG. 1 and then starts up the timer 49 in response to a control signal 66 fed from the controller 14, causing the timer 49 to start counting, or measuring, time from its initial value, e.g. “0”.

The timer 49 is continuously incremented while the camera 6 is using, or producing, a through picture, which is produced by thinning or reducing an image signal before actual pickup to display a thinned image on the display 30, or is continuously decremented while such a through picture is not used. In the instant alternative embodiment, a period of time for incrementing or decrementing the timer 49 has its upper and lower limits suitably selected beforehand, and therefore the timer 49 does not increment above the upper limit or decrement below the lower limit. More specifically, the timer 49, if reaching the upper limit during increment, is not incremented any further or, if reaching the lower limit during decrement, is not decremented any further.

Assume that the operator of the camera 6 turns on the power supply of the camera 6 and then depresses the through picture select button 39. Then, so long as a pickup mode signal 66 that allows pickup to be effected is input to the black level corrector 48 via the controller 14, the black level corrector 48 determines that a through picture is being used. On the other hand, so long as a playback mode signal 66 that allows images picked up to be reproduced is input to the black level corrector 48 via the controller 14, the black level corrector 48 determines that a through picture is not being used.

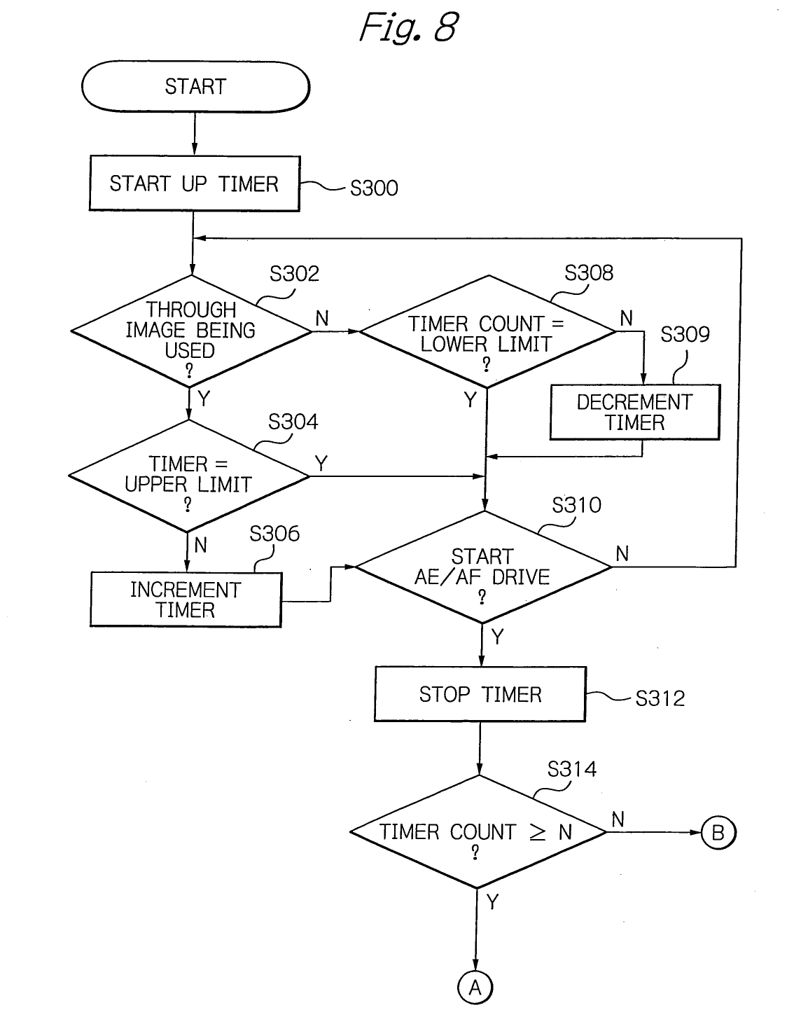

FIG. 8 is a flowchart demonstrating a specific method of driving the camera 60 in accordance with the instant alternative embodiment. As shown, on the power-up of the camera 6, the black level corrector 48 causes the timer 49 to start counting, or measuring, time from its initial value “0” in this example (step S300).

Subsequently, the black level corrector 48 determines whether or not the camera 6 is using a through picture on the basis of the pickup mode signal 66 or the playback mode signal 66 (step S302). The step S302 is followed by a step S304 if the answer of the step S302 is positive, Y, or followed by a step S308 if it is negative, N.

In the step S304, the black level corrector 48 determines whether or not the count of the timer 49 has reached the upper limit suitably selected beforehand. If the answer of the step S304 is negative, N, the black level corrector 48 increments the timer 49 (step S306); or otherwise (Y, step S304), the black level corrector 48 executes a step S310.

In the step S310, the black level corrector 48 determines whether or not the shutter release button 13 is depressed to its half-stroke position for starting AE/AF drive. If the answer of the step S310 is positive, Y, i.e., if an AE/AF drive start signal 66 is fed from the controller 14 to the black level corrector 48, the black level corrector 48 stores a right and a left shielded level in the same manner as in the procedure of FIG. 4 and then advances to a step S312. If the answer of the step S310 is negative, N, then the operation returns to the step S302 without resetting the timer 49.

In the step S312, the black level corrector 48 causes the timer 49 to stop counting time. The longer the period of time counted by the timer 49 up to the stop, the longer the period of time over which a through picture is used and presumably the higher the temperature of the CCD image sensor 34.

The black level corrector 48, stopped the timer 49 in the step S312, determines whether or not the period of time counted by the timer 49 is longer than a preselected threshold value N inclusive (step S314). If the answer of the step S314 is positive, Y the black level corrector 48 produces a one-output readout signal 66 and feeds it to the controller 14. In response, the controller 14 will then execute the step S206, FIG. 4, via the connection A. On the other hand, if the answer of the step S314 is negative, N, then the black level corrector 48 produces a usual, two-output readout signal 66 and feeds it to the controller 14. In this case, the controller 14 will execute the a step S210, FIG. 4, through the connection B. The sequence of steps described so far is executed while the shutter release button 13 is in its half-stroke position. After the depress of the shutter release button 13 to its full-stroke position, the steps s206 or s210 and following thereto will be executed as described with reference to FIG. 4.

As stated above, the present alternative embodiment switches the method of reading out signal charges from the CCD image sensor 34 on the basis of whether or not the period of time over which a through picture is used is greater than the threshold value N. Because the temperature of the CCD image sensor 34 generally rises when a through picture is used, the alternative embodiment determines, if the above period of time is greater than the threshold value N, that the temperature of the CCD image sensor 34 is high, causes actual pickup to be executed in the one-output readout mode, and then uses the shielded level of the left subregion 156 to execute black level correction with the entire valid pixel region. This is because considering that the temperature of the CCD image sensor 34 is presumably high, it is desirable to use the one-output readout mode rather than the usual, two-output readout mode to obviate differences in brightness and color shifts between the right and left regions and enhance image quality.

By contrast, if the period of time over which a through picture is used is smaller than the threshold value N, then the alternative embodiment determines that the temperature of the CCD image sensor 34 is low, applies the usual, two-output readout mode to actual pickup, and then uses the shielded levels of the two subregions 158 and 156 to execute black level correction with the right and left subregions 158 and 156, respectively. This is because considering that the temperature of the CCD image sensor 34 is presumably low, differences in OB step between the right and left subregions 158 and 156 is presumably small, so that brightness, color shifts and other image defects do not occur even if the right and left subregions 158 and 156 are subject to black level correction independently of each other. In addition, such black level correction successfully reduces the image signal reading time.

It is to be noted that the alternative embodiment assigns an upper limit to the timer 49 such that the temperature of the CCD image sensor 34 does not rise above a predetermined expected level, and assigns a lower limit to the timer 49 such that the above temperature does not drop below a predetermined expected level.

In summary, it will be seen that the present invention provides an image pickup apparatus insuring high-quality images substantially free from, or minimized in, differences in brightness and color shifts a scribable to black level correction between divided subregions, e.g., a right and a left subregion of an image, even when the temperature of an image sensor to which a plurality of different readout modes, including a usual, two-output readout mode, are applicable rises above a preselected level. A method of driving such an image pickup apparatus is also attained.

The entire disclosure of Japanese patent application No. 2006-081557 filed on Mar. 23, 2006, including the specification, claims, accompanying drawings and abstract of the disclosure is incorporated herein by reference in its entirety.

While the present invention has been described with reference to the particular illustrative embodiments, it is not to be restricted by the embodiments. It is to be appreciated that those skilled in the art can change or modify the embodiments without departing from the scope and spirit of the present invention.

What is claimed is:

1. An image pickup apparatus comprising:
an image sensor including a plurality of output portions and for photoelectrically converting light incident from a field to thereby produce an image signal via said plurality of output portions;
a temperature sensor for sensing a temperature of said image sensor;
a driver for driving said image sensor such that the image signal is output via one of said plurality of output portions if the temperature sensed by said temperature sensor is higher than a predetermined value inclusive or is output via at least two of said plurality of output portions if the temperature is lower than the predetermined value; and
a black level corrector for using, when the image signal is output via one of said plurality of output portions, a predetermined single value as a reference to execute black level correction on the image signal, or using, when the image signal is output via at least two of said plurality of output portions, a particular predetermined value as a reference to execute black level correction on each of image signals output from respective output portions.

2. The apparatus in accordance with claim 1, wherein the predetermined single value comprises a shielded signal level of any subregion of a valid pixel region included in said image sensor while the particular predetermined value comprises a shielded level of each subregion of said valid pixel region in which the image signal to be output from the respective output portion is produced.

3. The apparatus in accordance with claim 1, wherein said plurality of output portions comprise two output portions.

4. The apparatus in accordance with claim 3, wherein said plurality of output portions are configured to output image signals produced in subregions defined by bisecting said valid pixel region in a right-and-left direction.

5. An image pickup apparatus comprising:
an image sensor including a plurality of output portions and for photoelectrically converting light incident from a field to thereby produce an image signal via said plurality of output portions;
a signal level monitor for monitoring a signal level of an optical black region surrounding a valid pixel region of said image sensor;
a driver for driving said image sensor such that the image signal is output via one of said plurality of output portions if the signal level monitored by said signal level monitor is higher than a predetermined value inclusive or is output via at least two of said plurality of output portions if the signal level is lower than the predetermined value; and
a black level corrector for using, when the image signal is output via one of said plurality of output portions, a predetermined single value as a reference to execute black level correction on the image signal or using, when the image signal is output via at least two of said plurality of output-portions, a particular predetermined value as a reference to execute black level correction on each of image signals output from respective output portions.

6. The apparatus in accordance with claim 5, wherein the predetermined single value comprises a shielded signal level of any subregion of a valid pixel region included in said image sensor while the particular predetermined value comprises a shielded level of each subregion of said valid pixel region in which the image signal to be output from the respective output portion is produced.

7. The apparatus in accordance with claim 5, wherein said plurality of output portions comprise two output portions.

8. The apparatus in accordance with claim 7, wherein said plurality of output portions are configured to output image signals produced in subregions defined by bisecting the valid pixel region in a right-and-left direction.

9. An image pickup apparatus comprising:
an image sensor including a plurality of output portions and for photoelectrically converting light incident from a field to thereby produce an image signal via said plurality of output portions;
a timer for counting a period of time over which said image sensor outputs an image signal for a through image of the field when a power supply is on;
a driver for driving said image sensor such that the image signal is output via one of said plurality of output portions if the period of time counted by said timer is longer than a predetermined value inclusive or is output via at least two of said plurality of output portions if the period of time is shorter than the predetermined value; and
a black level corrector for using, when the image signal is output via one of said plurality of output portions, a predetermined single value as a reference black to execute level correction on the image signal or using, when the image signal is output via at least two of said plurality of output portions, a particular predetermined value as a reference to execute black level correction on each of image signals output from respective output portions.

10. The apparatus in accordance with claim 9, wherein the predetermined single value comprises a shielded signal level of any subregion of a valid pixel region included in said image sensor while the particular predetermined value comprises a shielded level of each subregion of said valid pixel region in which the image signal to be output from the respective output portion is produced.

11. The apparatus in accordance with claim 9, wherein said plurality of output portions comprise two output portions.

12. The apparatus in accordance with claim 11, wherein said plurality of output portions are configured to output image signals produced in subregions defined by bisecting the valid pixel region in a right-and-left direction.

13. A method of driving an image pickup apparatus, comprising the steps of:
sensing a temperature of an image sensor included in a pickup section and photoelectrically converting light incident from a field to thereby produce an image signal;
outputting the image signal via one of a plurality of output portions included in the image sensor if the temperature sensed is higher than a predetermined value inclusive;
outputting the image signal via at least two of the plurality of output portions if the temperature sensed is lower than the predetermined value;
using, when the image signal is output via one of the plurality of output portions, a predetermined single value as a reference to execute black level correction on the image signal by; and
using, when the image signal is output via at least two of the plurality of output portions, a particular predetermined value as a reference to execute black level correction on each of image signals output from respective output portions.

14. The method in accordance with claim 13, wherein the predetermined single value comprises a shielded signal level of any subregion of a valid pixel region included in the image sensor while the particular predetermined value comprises a shielded level of each subregion of the valid pixel region in which the image signal to be output from the respective output portion is produced.

15. The method in accordance with claim 13, wherein the plurality of output portions comprise two output portions.

16. The method in accordance with claim 15, wherein the plurality of output portions are configured to output image signals produced in subregions defined by bisecting the valid pixel region in a right-and-left direction.

17. A method of driving an image pickup apparatus, comprising the steps of:
measuring a signal level of an optical black region surrounding a valid pixel region of an image sensor included in a pickup section and photoelectrically converting light incident from a field to thereby produce an image signal;
outputting the image signal via one of a plurality of output portions included in the image sensor if the signal level measured is higher than a predetermined value inclusive;
outputting the image signal via at least two of the plurality of output portions if the signal level measured is lower than the predetermined value;
using, when the image signal is output via one of the plurality of output portions, a predetermined single value as a reference to execute black level correction on the image signal; and
using, when the image signal is output via at least two of the plurality of output portions, a particular predetermined value as a reference to execute black level correction on each of image signals output from respective output portions.

18. The method in accordance with claim 17, wherein the predetermined single value comprises a shielded signal level of any subregion of a valid pixel region included in the image sensor while the particular predetermined value comprises a shielded level of each subregion of the valid pixel region in which the image signal to be output from the respective output portion is produced.

19. The method in accordance with claim 17, wherein the plurality of output portions comprise two output portions.

20. The method in accordance with claim 19, wherein the plurality of output portions are configured to output image signals produced in subregions defined by bisecting the valid pixel region in a right-and-left direction.

21. A method of driving an image pickup apparatus, comprising the steps of:
counting a period of time over which an image sensor included in a pickup section outputs an image signal for a through image of a field when a power supply is on, the image sensor photoelectrically converting light incident from a field to thereby produce the image signal;
outputting the image signal via one of a plurality of output portions included in the image sensor if the period of time counted is longer than a predetermined value inclusive;
outputting the image signal via at least two of the plurality of output portions if the period of time counted is shorter than the predetermined value;
using, when the image signal is output via one of the plurality of output portions, a predetermined single value as a reference to execute black level correction on the image signal; and
using, when the image signal is output via at least two of the plurality of output portions, a particular predetermined value as a reference to execute black level correction on each of image signals output from respective output portions.

22. The method in accordance with claim 21, wherein the predetermined single value comprises a shielded signal level of any subregion of a valid pixel region included in the image sensor while the particular predetermined value comprises a shielded level of each subregion of the valid pixel region in which the image signal to be output from the respective output portion is produced.

23. The method in accordance with claim 21, wherein the plurality of output portions comprise two output portions.

24. The method in accordance with claim 23, wherein the plurality of output portions are configured to output image signals produced in subregions defined by bisecting the valid pixel region in a right-and-left direction.
